(19) United States
(12) Patent Application Publication
(10) Pub. No.: US 2023/0262169 A1
(43) Pub. Date: Aug. 17, 2023

(54) Core Sound Manager

(71) Applicant: Immersitech, Inc., Rochester, NY (US)

(72) Inventors: Isaac Weston Mosebrook, Somerville, MA (US); David Frederick Horan, Lakeville, NY (US); Ian David Griffith Lawson, Brooklyn, NY (US)

(73) Assignee: Immersitech, Inc., Rochester, NY (US)

(21) Appl. No.: 18/109,542

(22) Filed: Feb. 14, 2023

Related U.S. Application Data
(60) Provisional application No. 63/310,175, filed on Feb. 15, 2022.
(60) Provisional application No. 63/345,112, filed on May 24, 2022.

(51) Int. Cl. H04M 3/56; H03G 5/16; H03G 3/30; G10L 25/78

(52) U.S. Cl. CPC H04M 3/568; H03G 5/165; H03G 3/3089; G10L 25/78

(57) ABSTRACT

A system and method provide audio processing for on-line communications, including the elimination of unwanted and disruptive noises, enhancing the clarity of the participants voices, and further processing to establish an immersive 3D spatial audio experience. The combination of the three main processing components which make up the Core and the processes of how audio streams and related data are manipulated leveraging machine learning algorithms and finely tuned component configurations to establish a clear, immersive on-line audio communication listening experience for each participant is a primarily unique feature of the present invention.

### CROSS-REFERENCE TO RELATED APPLICATIONS

The present application claims priority to and the benefit of U.S. provisional patent application Ser. No. 63/345,112, filed May 24, 2022, entitled CORE SOUND MANAGER and U.S. provisional patent application Ser. No. 63/310,175, filed Feb. 15, 2022, entitled CORE SOUND MANAGER, all of the contents of applications being incorporated herein by reference in their entireties.

### BACKGROUND

The present invention relates to a system and method for providing comprehensive processing of live and recorded audio in support of on-line communications commonly used in business teleconferencing, multi-player on-line gaming, social entertainment group chat communications systems, and the like. The audio processing system is focused on the elimination of background noise, while maintaining and enhancing clarity of the participants voice, and then further enhancing the audio to deliver an immersive three-dimensional (3D) spatial audio experience for each participant.

### SUMMARY

In an illustrative embodiment, a computer implemented multi-dimensional audio conferencing method for audio and related data processing of noise cancellation, participant voice clarity enhancements, and immersive 3D spatial audio output to participants in an audio or video on-line communications ecosystem is disclosed. The method includes:
in one or more first processing components:
   receiving from on-line communication participants audio streams;
   resampling the audio streams to ensure the audio streams are sampled at the same sample rate;
   removing noise via a noise cancellation process executed on the audio streams;
   executing an equalization process to improve sound quality of the audio streams; and
   leveling the audio streams to a common volume level for the participants; and
in one or more second processing components:
   receiving, as input, the leveled audio streams;
   assigning each participant to a 3D unique position on a computer generated map;
   determining a direction on the map of each participant relative to the other remaining participants;
   attenuating a given audio stream of a speaking participant to an attenuated audio stream such that the attenuated audio stream is representative of a distance between a speaking participant and the one or more listening participants;
   converting the given attenuated audio stream to a converted sound corresponding to the direction of the speaking participant relative to the one or more listening participants;
   for at least some of the listening participants, performing crosstalk cancelation on the converted sound; and
   performing a limiting process on each converted audio stream.

In another illustrative embodiment, an automatic equalization process for an audio or video on-line communications system comprises:
providing a processor to run said automatic equalization process with a generalized target curve which maps a spectral character of speech of a typical on-line communications participant audio;
receiving from an on-line communications participant, an audio stream into said processor;
based on a frequency domain analysis by said processor of at least one block of said audio stream, adjusting said generalized target curve to match a fundamental pitch of said on-line communications participant by said processor to generate an adapted target curve;
   generating by said processor a transfer function for a filter based on said adapted target curve; and
convolving by said processor said audio stream with said filter to provide substantially in real time an enhanced speech.

In yet another illustrative embodiment, an automatic gain control process for an audio or video on-line communications system comprises:
providing a process to run said automatic gain control process with an equal loudness filter which filters audio according to a natural frequency curve of human hearing; receiving from an on-line communications participant, an audio stream into said processor;
filtering at least one block of said audio stream by said equal loudness filter to generate a filtered audio stream block;
calculating by said processor a gain factor K based on an RMS power of said filtered audio stream block, a RMS power of a previous filtered audio stream block; and an average power measurement of two or more of said filtered audio stream blocks; and
applying by said processor said gain factor K to said audio stream to maintain substantially in real time, a desired volume for said on-line communications participant.

In another illustrative embodiment, a computer system comprises:
a memory storing instructions: and
a processor coupled with the memory to execute the instructions, the instructions configured to instruct the processor to provide clear immersive 3D audio to participants in an audio or video on-line communications ecosystem;
receive, by the processor, from each on-line communications participant an audio stream and a related data stream into a first processing component;
resample, by the first processing component, each received audio stream to ensure all audio streams are sampled at the same sample rate;
remove noise, by the first processing component, via a noise cancellation process on each resampled audio stream;
improve the sound quality, by the first processing component, via an automatic equalization process on each noise removed audio stream;
level, by the first processing component, via an automatic gain control process on each improved sound quality audio stream;
3D spatialize, by the first processing component, the leveled audio stream from each speaking participant to each other listening participant; said spatialization comprising assigning, via a second processing component, each conference participant to a unique position on a computer generated map based upon the data stream related to each leveled audio stream, wherein the plurality of conference participants includes speaking participants and listening participants;
determining a direction on the map of each participant from each other participant, attenuating, by the first processing component, the 3D spatialized audio stream to an attenuated audio stream such that the attenuated audio stream is representative of a distance between the one speaking participant and each of the listening participants; and
converting, by the first processing component, the attenuated voice sound to a converted sound corresponding to the direction to each of the listening participants from the speaking participant;
for each participant listening to the conference via a means other than headphones, perform, by the first processing component, crosstalk cancelation on each said converted audio stream; and
perform, by the first processing component, a limiting process on each converted audio stream.

The combination of the individual elements, which are summarized as three processing component managers, make up the Core. The processes of how audio streams and related data are manipulated to deliver speaker or headphone output to be heard uniquely by each participant is a primary feature of the present invention. The systems of the present art cannot combine all three into a single integrated unit to provide an easy-to-use processing component for use in an existing or new on-line communication platform.

### BRIEF DESCRIPTION OF THE DRAWINGS

Embodiments of the present invention will be described by reference to the following drawings, in which like numerals refer to like elements, wherein:

FIGS. 1A, 1B, and 1C illustrate a preferred embodiment of a Core management system to provide audio and related data processing for on-line communications to participants in an audio or video on-line communications ecosystem, according to one or more illustrative embodiments;

FIGS. 2A, 2B, 2C, and 2D illustrate process flow diagrams depicting a host and client adapter implementations interface in relation to a Sound Manager to provide audio processing focused on noise removal, voice clarity enhancements and immersive three-dimensional (3D) audio to participants in an audio or video on-line communications session, according to one or more illustrative embodiments;

FIG. 3 illustrates an exemplative process flowchart for multiple participants engaged in an on-line communication session via the Core management system according to one or more illustrative embodiments;

FIG. 4 illustrates an exemplative process flow diagram depicting the Environment Manager of the Core management system receiving environment audio characteristic parameters to establish participant locations relative to each other in an audio or video on-line communications session, according to one or more illustrative embodiments;

FIG. 5 illustrates a process flow diagram illustrating the Event Manager of the Core management system for managing real-time participant audio positioning and/or optional client-side audio position settings related to the participants audio profile and/or real-time movement in an audio or video on-line communications session, according to one or more illustrative embodiments;

FIG. 6 illustrates the client adapter of the Core management system for interacting with the Event Manager to communicate real-time participant audio movement events and/profile settings from the client application an edge/input, according to one or more illustrative embodiments:

FIG. 7 illustrates a client ecosystem for communications between the host and multiple clients, according to one or more illustrative embodiments:

FIG. 8 illustrates an embodiment of exemplative devices used to provide audio processing for on-line communications to participants in an audio or video on-line communications ecosystem, according to one or more illustrative embodiments;

FIGS. 9A and 9B illustrate representative architectures and systems associated with the devices of FIG. 8 capable of implementing the Core management system, according to one or more illustrative embodiments;

FIG. 10 illustrates an exemplative process flowchart of the Core management system according to one or more illustrative embodiments;

FIG. 11 illustrates a representative example of the whisper mode of the Core management system for establishing private communication between participants while still engaged in a main conference session, according to one or more illustrative embodiments; and

FIG. 12 illustrates a representative example of a sidebar mode for establishing private communication for a sub-conference session of the main conference session, according to one or more illustrative embodiments.

### DETAILED DESCRIPTION

In the various figures, data transmission is denoted by a dashed arrow; an audio transmission is denoted by a squiggly arrow; and a logical grouping is denoted by a hatched line surrounding the logical group.

The present invention relates to a system and methods which provide audio and related data processing for on-line communications, including the elimination of unwanted and disruptive noises, while enhancing the clarity of the participants voices, and then virtually positioning each of the participants audio to create a more immersive 3D spatial audio experience.

### LISTING OF PARTS

The following is a listing of elements presented in the drawings:

| | |
|---|---|
| 10 | Internet; |
| 50 | Host Adapter; |
| 54 | Host API; |
| 55 | Host Communications System; |
| 57 | Host Ecosystem; |
| 70 | Host to Client Audio-Video Streams; |
| 80 | Client Adapter; |
| 84 | Client Adapter API; |
| 85 | Client Applications; |
| 87 | Client Ecosystem; |
| 100 | Core; |
| 200 | Event Manager; |
| 250 | Event Manager API; |
| 255 | Event Manager Queue; |
| 290 | Event Manager API Secure WebSocket; |
| 300 | Environment Manager; |
| 320 | Environment Configuration File; |
| 400 | Sound Manager; |
| 420 | 3D Mixer; |
| 600 | Client Device; |
| 622 | Central Processing Unit (CPU); |
| 625 | Computer Bus; |
| 626 | Power Supply; |
| 630 | Memory; |
| 634 | Read Only Memory (ROM); |
| 640 | Basic Input Output System (BIOS); |
| 641 | Operating System; |
| 642 | Applications; |
| 644 | Data Storage; |
| 645 | Browser; |
| 650 | Network Interface(s); |
| 652 | Audio Interface; |
| 654 | Display; |
| 656 | Keypad; |
| 660 | Input/Output Interface; |
| 662 | Haptic Interface; |
| 668 | Microphone; |
| 700 | Internal Architecture; |
| 702 | Computer Bus(es); |
| 704 | Memory; |
| 706 | Storage Medium/Media; |
| 708 | Audio Input; |
| 710 | Display Interface; |
| 712 | Processing Unit(s); |
| 714 | Network Interface; |
| 716 | Keyboard Interface; |
| 718 | Pointing Device Interface; |
| 722 | Other Interfaces; |
| 724 | Audio Output; |
| 1010 | Participant 1; |
| 1020 | Resampling Process; |
| 1030 | Noise Cancellation Process; |
| 1035 | Automatic Equalization (EQ) Control Process; |
| 1040 | Automatic Gain Control Process; |
| 1050 | Participant 1 Processed input; |
| 1070 | Three-Dimensional (3D) Mixer Processing; |
| 1075 | Three-Dimensional (3D) Coordinates for each Participant; |
| 1080 | Cross-Talk Cancellation Process; |
| 1090 | Limiting Process; |
| 1093 | Master Gain Control Process; |
| 1095 | Participant 1 mixed output; |
| 1110 | Participant 2; |
| 1150 | Participant 2 Processed input; |
| 1195 | Participant 2 mixed output; |
| 1210 | Participant 3; |
| 1250 | Participant 3 Processed input; |
| 1295 | Participant 3 mixed output; |
| 2000 | Simplified participant audio processing overview; |
| 2020 | Participant audio input to conference via Device Microphone; |
| 2030 | Participant audio from Client Application to Host Communication |
| | System; |
| 2040 | Audio passed from Host to Host Adapter for processing in Sound |
| | Manager; |
| 2050 | Environment Manager loads Environment Configuration into |
| | Sound Manager to process audio; |
| 2060 | Audio processing flow within Sound Manager; |
| 2070 | Participant audio positioning can be updated in real-time based on |
| | Client Application data; |
| 2080 | Processed audio from Sound Manager is returned to Host |
| | Communication System; |
| 2090 | Host Communication System sends processed audio back to Client |
| | Application for audio output on Client Device; |
| 3000 | Conference Room A; |
| 3010 | Main Room A; |
| 3020 | Whisper Room A; |
| 3030 | Data/Audio Communications Between Main Room and Whisper |
| | Room; |
| 4000 | Conference Room B; |
| 4010 | Main Room B; |
| 4020 | Sidebar Room B; and |
| 4030 | Data/Audio Communications Between Main Room and Sidebar |
| | Room. |

### Core

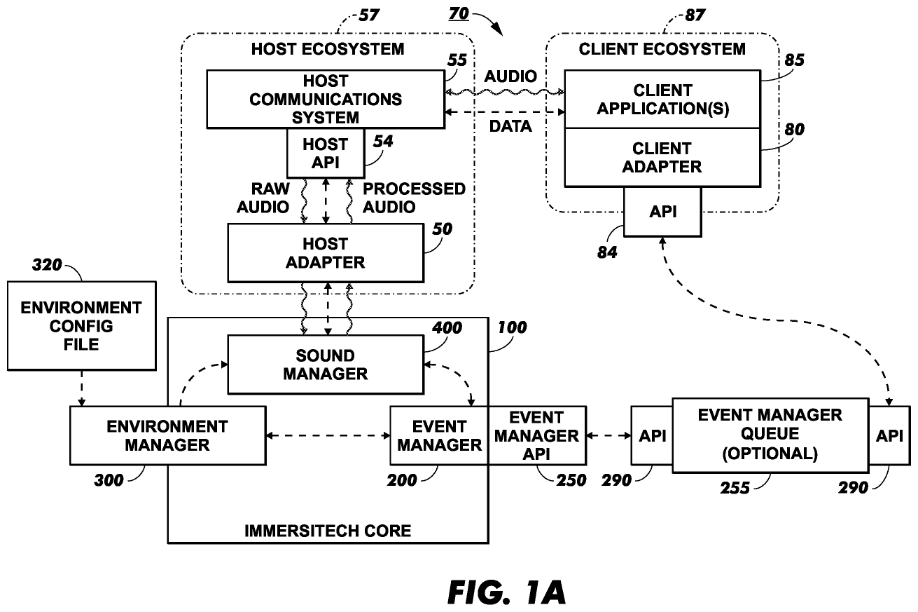

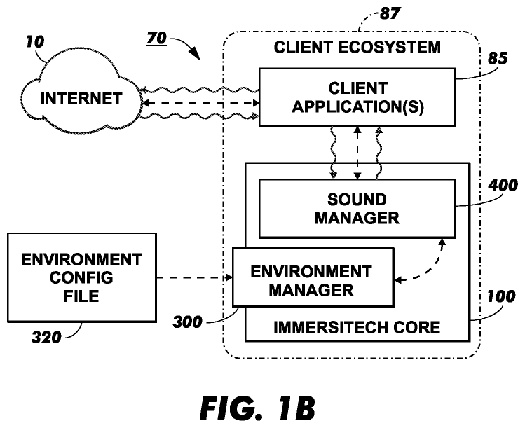

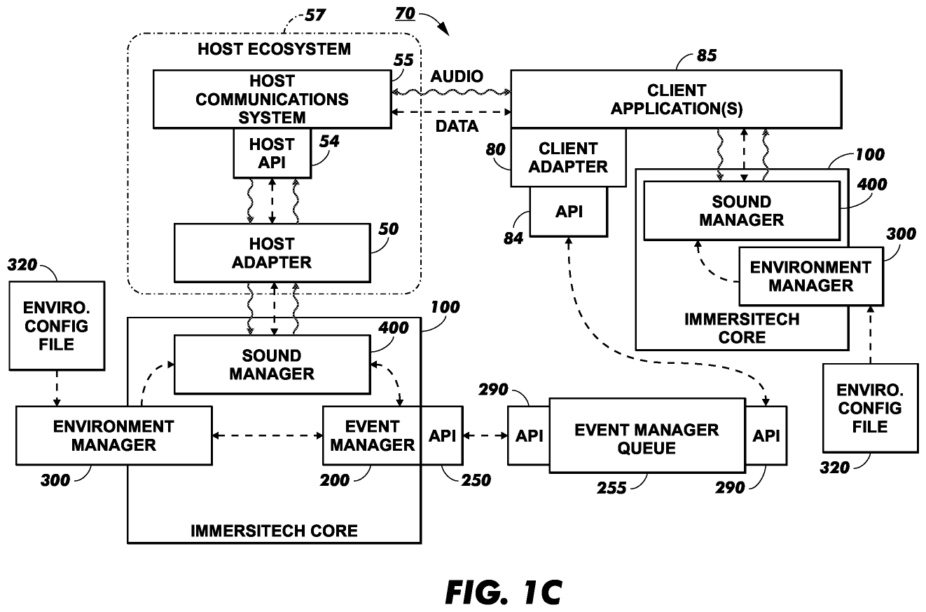

Referring initially to FIGS. 1A, B, and C, an exemplary embodiment of a Core management system according to the principles of the present invention is illustrated. The Core management system is capable of providing audio output that leverages machine learning algorithms to identify and remove disruptive noises from each participants input while enhancing participant voices by applying algorithmic processes to adjust for the optimal balance of voice clarity and volume, which is then spatially mixed to establish a more immersive, engaging and less fatiguing communication experience. FIGS. 1A-1C illustrate various components for processing audio and related data and delivering an associated output in an audio or video on-line communications ecosystem. A processing component, referred herein as Core 100, provides an audio engineer and/or software developer the ability to fully configure a virtual on-line communications session, virtual lecture hall, virtual auditorium, virtual gaming environment or other such arbitrarily arranged virtual communications space to provide clear, immersive spatial audio to all participants attending the virtual on-line communications session, lecture, competition or performance, and further to tailor the output received/heard by each participant to optimize the audio profiles of each individual listener.

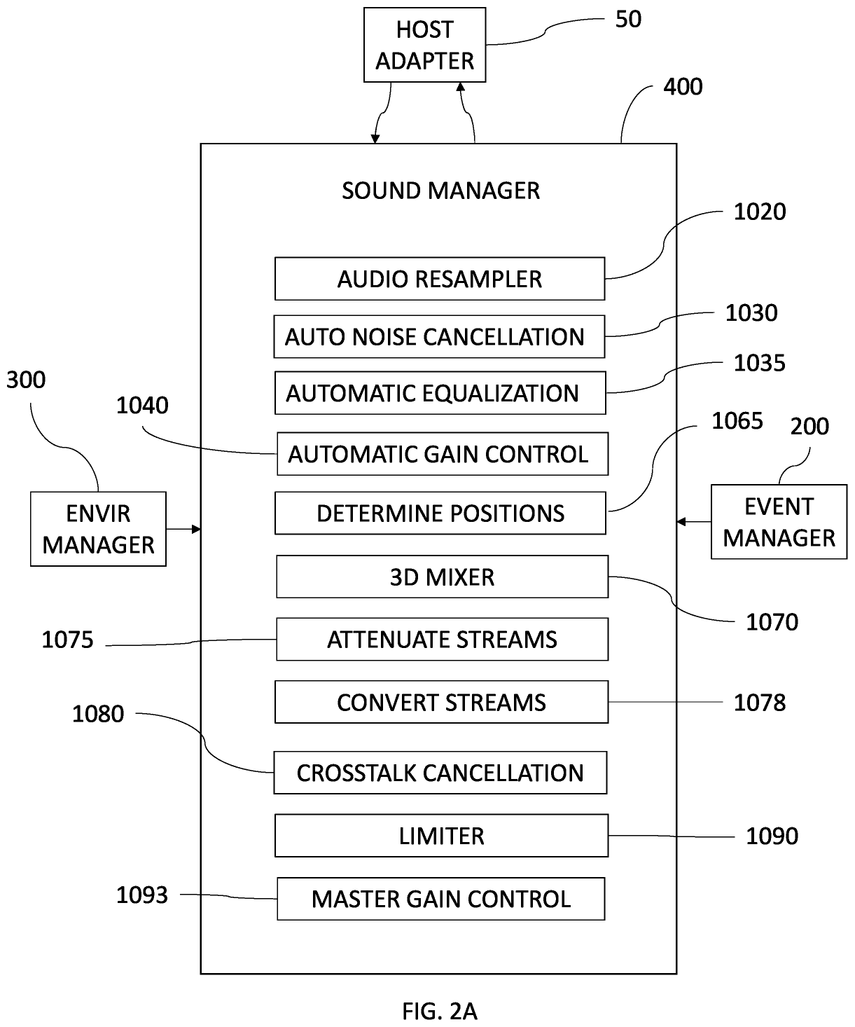

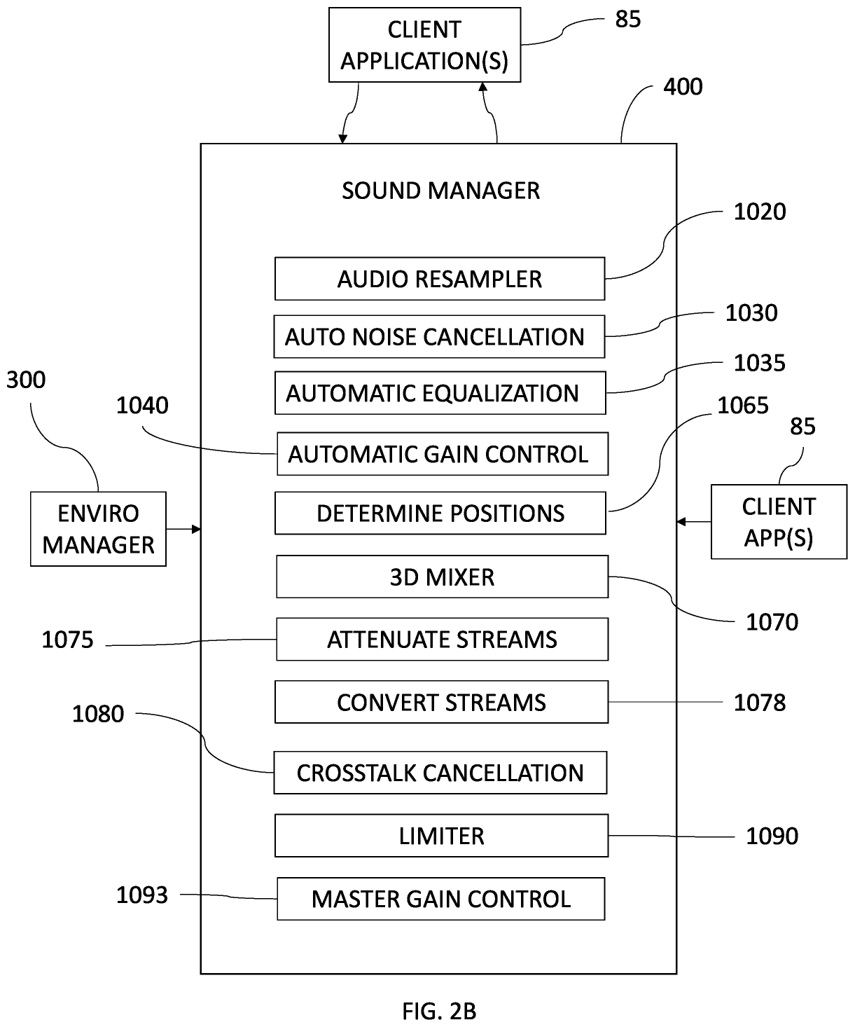

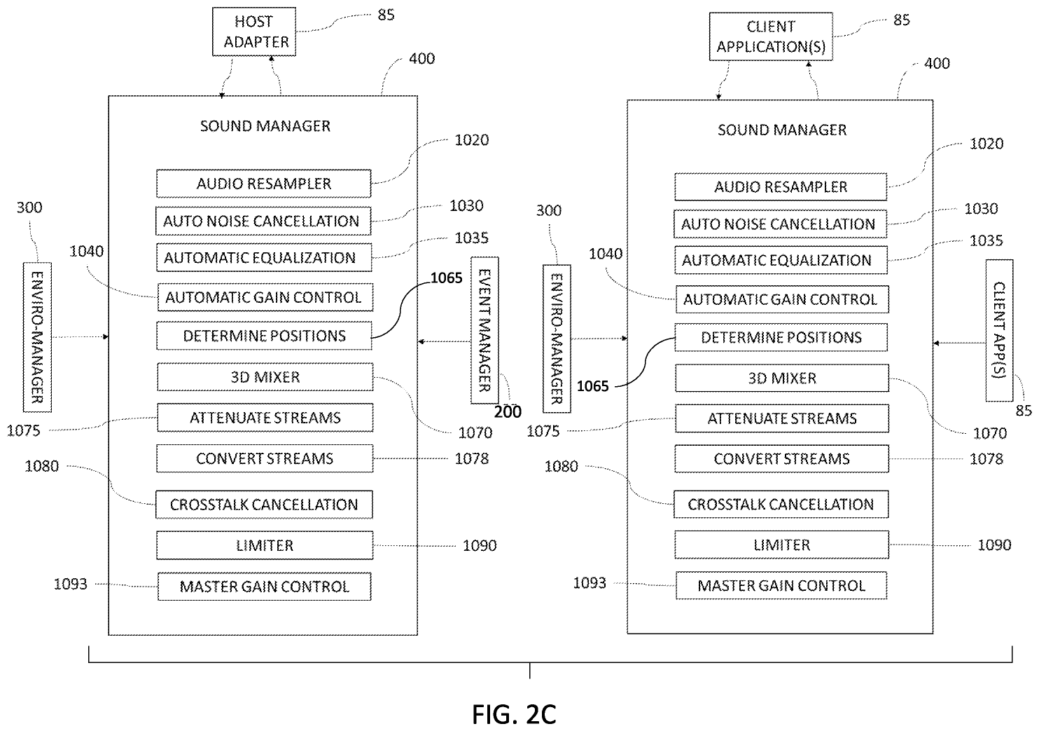

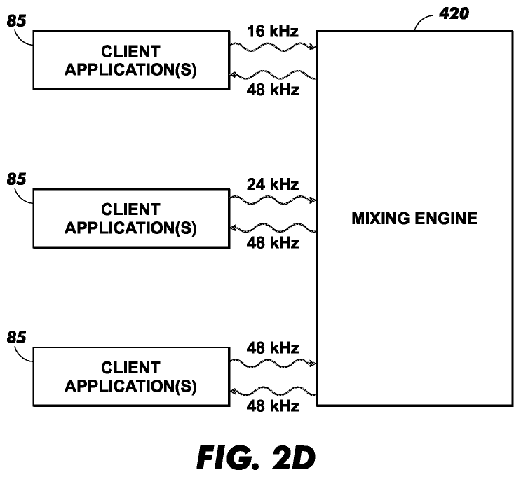

Additionally, referring to FIGS. 2A, B, C, and D, the process used by a key processing component of the Core 100, the Sound Manager 400, is provided.

The combination of providing customer configurable settings and related integration software tools, including Adapters and application programming interfaces (APIs), which allow for a simplified implementation of the Core within an on-line communications system in comparison to existing tools which are often implemented one at a time and not integrated together for optimal performance.

Referring to FIGS. 1A-1C, the Core 100 is a processing component that directs the actions of other sub-components including an Event Manager 200, an Environment Manager 300, and a Sound Manager 400. The Core 100 provides the interface for audio and related data between the processing components and a host adapter 50 to communicate with a host communication system 55. In the present embodiment, the host communication system 55 may represent any communications platform a software developer may want to integrate with the Core 100 such as business conference call platform, multi-player on-line communications system for gaming, social entertainment group chat communications system, and the like. The host adapter 50 relays audio and related data to and/or from the host communication system 55 to the Core 100. The host adapter 50 comprises an audio processing component and a data processing component working in unison and further watches for specific data events which should be processed. In illustrative embodiments, the Core 100 comprises three primary processing components (also referred to as managers), an Event Manager 200, an Environment Manager 300, and a Sound Manager 400 and is particularly well streamlined as a result of defined, optimized configurations, such as having all audio and related data converted upon input to the same data structure, which allow these three primary processing components to interact seamlessly with each other and be managed to create the configured audio output. The primary processing components may also interact with the application programming interfaces (APIs) Event Manager API 250 and a client adapter API 84 that the primary processing components use to communicate between the host communication system 55 and client applications 85. As those skilled in the art are aware multiple client applications may be served by this system though only one is illustrated in the figures to aid in clarity.

A non-exhaustive sample representative system would be one wherein the client ecosystem 87 consists of a portable computing device, e.g., a Lenovo Yoga 730 laptop with built in microphone and speakers connected via the internet to the host communication system 55 on one or more private and/or public cloud services, e.g., Amazon Web Services (AWS) Cloud Services, executing one or more communication applications, for example, and without limitation, a FreeSWITCH communications application with the Core 100 installed.

In one exemplative embodiment illustrated in FIG. 1A, the Event Manager 200 and the external Event Manager API 250 provide a means for monitoring and relaying messages to and/or from internal stack processing components such as the Environment Manager 300 and the Sound Manager 400, the host communication system 55 via the host API 54 and the host adapter 50, and any attached client applications 85. The embodiment illustrated in FIG. 1A may be considered to be a host side operational mode application. The Event Manager 200 receives and sends pertinent data messages to and from both the Environment Manager 300 and the Sound Manager 400 in the Core 100 stack. The Event Manager 200 acts a message broker, ensuring the various system processing components and external entities are notified of pertinent system events. The Event Manager API 250 provides an optional bi-directional communications channel 290 for client applications 85 to send pertinent messages to the Core 100 and for the Event Manager 200 to send messages back to the attached client applications 85 via the client adapter 80 and the client adapter API 84. The bi-directional channel 290 for communication between the client adapter 80 and the Event Manager API 250 is preferably a secure web socket connection. Each participant in a meeting will use an instance of the client application 85 to connect to a meeting. This will allow each authorized participant to make changes in the meeting such as adjusting their location within the virtual room or making use of specialized features such as whisper mode (which will be described later in this specification) and the like that can securely send messages to the Event Manager API 250. These messages can then be processed both internally by the Core 100 and other connected client applications 85.

The Environment Manager 300 processing component provides a means to define and use multiple environment configurations for an on-line communications session. In addition to the various environmental acoustic parameters, the Environment Manager 300 also generates and provides a participant-to-coordinate mapping which allows the Event Manager 200 connected client applications 85 to manage participant locations by means of allowing real-time participant-initiated movements. In communication with the Core 100, the host adapter 50 sends audio stream preferably references directly to Event Manager 200. In certain embodiments, the host adapter 50 may also send video stream references directly to the Environment Manager 300. In turn, the Environment Manager 300 passes these references to the Sound Manager 400 as input for the Sound Manager 400 when processing/mixing the audio streams. The Sound Manager 400 processing component is the main audio processing and mixing system in the Core 100. The Sound Manager 400 provides capabilities for 3D audio mixing, noise reduction, and improved clarity of participant voices. The functioning of the Sound Manager 200 will be described in further detail hereinbelow.

The host communication system 55 and the associated client application 85 transmit audio streams and optionally video streams independent of the Core 100 as they would without obtaining the improved audio processing of the Core 100. In illustrative embodiments, usage of the Core 100 will not interrupt or interfere with the transmissions between the host communication system 55 and the client applications 85.

In one illustrative embodiment, the client adapter 80 can be included in the client application 85 to form one client ecosystem 87 that will both communicate natively with the host communication system 55, and also with the Event Manager API 250 for 3D control messages.

In the exemplative embodiment illustrated in FIG. 1A, the client adapter 80 is software provided as a library or tool allowing the client application 85 to send and/or receive messages with the Event Manager API 250 which facilitates the sending and receiving of pertinent 3D command messages between the client application 85 and the Core 100. This also allows the same client application 80 to receive messages from the Event Manager API 250 and update the client application 80 user interface accordingly. As an example, if a participant leaves the meeting, the Event Manager 200 will pass that information on to the client application 85.

The spatial audio enhancing techniques taught by the present invention are specifically used for the application of on-line communications in any or all its forms such as business audio/video conferencing, distance learning classes, interactive concerts/sports performances, social entertainment chat communications and the like. The present invention provides for the ability to deploy each of these tools and effects as separate processing components which may be individually selected to be placed in service depending upon the circumstances of the particular virtually defined audio environment and all work seamlessly in concert with each other.

Referring to FIG. 1B, and the illustration of a client side operational mode, the client application 85 may be any on-line communications application used by an end user such as a Zoom client, a Microsoft Teams client, or the like. The client application 85 may be either a software application developed by the maker of the host communication system 55 for use with the host communication system platform or a third-party application targeted to be compatible with the host communication system 55. Each end user will have a client application 85. Each client application 85 does not inherently know anything about virtual 3D locations of the individual speakers and listeners, but through the Event Manager API 250 it can be made aware of events in the on-line communications session the user is participating in. The Sound Manager 200 knows where each participant is located and provides this information to the Environment Manager 300, host adaptor 50 and also to the client adapter 80 via an API 85 and the Event Manager 200.

The client adapter 80 is not related to the Core 100 and therefore needs no specific configurations to work with the Core 100. But the client adapter 80 allows the client adapter API 84 to send info to the Event Manager API 250.

In FIG. 1C, a hybrid operational mode is illustrated wherein the host communication system 55 would be any meeting facilitation platform such as a Zoom server, a Microsoft Teams server hosting the meeting itself, or the like.

The Event Manager 200 processing component provides an API interface 250 between end-user client applications 85 and the Core system 100.

The host adapter 50 provides a translator for the host communication system 55 to communicate the Core 100. The host adapter 50 is a standalone processing component separate from the unified communications (UC) Core which translates messages or events from the host communication system 55 into commands the rest of the Core stack can understand. As such the host adapter is outside of the Core 100 itself and is merely an adaptor.

Moving audio sources around an environment is a highly complex transformation, particularly when the audio from individual sources is enhanced for optimal audio rendering, and the algorithms of the Core 100 allow a software developer to readily deploy audio sources to any location within the virtual Environment. A representative example of such highly complex transformation is provided in commonly assigned U.S. Pat. No. 9,161,152 to Gleim, entitled Multi-Dimensional Virtual Learning System and Method, the entire contents of which are hereby incorporated by reference in its entirety.

### Sound Manager

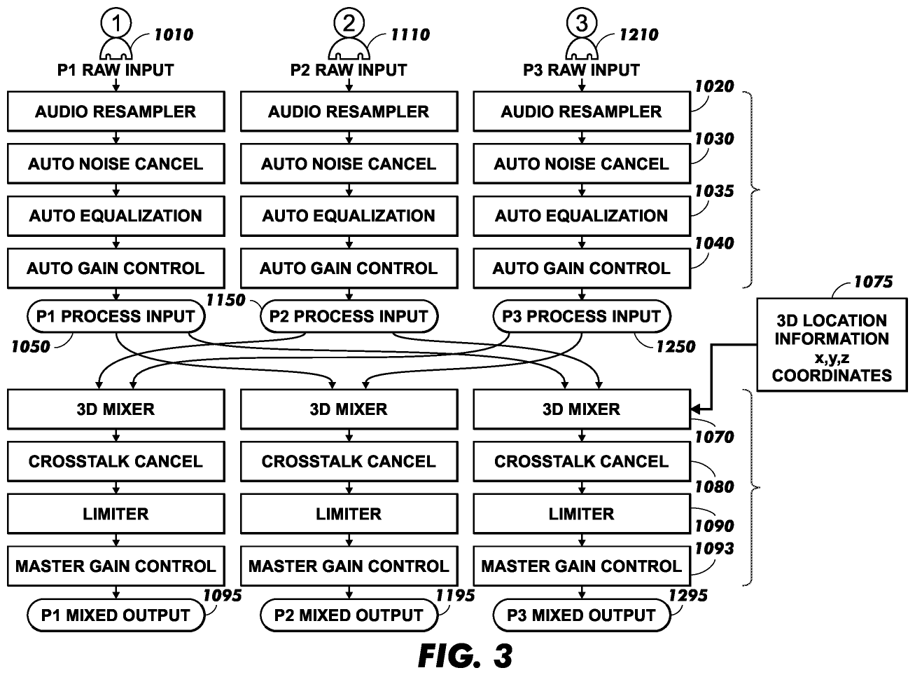

The Sound Manager 400 is the main audio and related data processing component in the Core 100 in that within the one unit it provides noise removal, voice clarity improvements, and 3D spatial audio and related data processing. FIGS. 2A-2D and FIG. 3 provide representative examples of operation of the Sound Manager 400 and its interaction with the other processing components of the Core 100. Referring to FIG. 3, the operation of the Sound Manager 400 is illustrated for an example audio on-line communications session with three participants. An on-line communications session held virtually could literally have a significant number of participants, but to keep the example simple, a three-person on-line communications session was chosen to demonstrate. Participant audio and related data from each of three participants 1010, 1110, and 1210 are input as individual audio streams as the host communication system sends each audio input via an audio stream into the Core and more particularly the Sound Manager 400 through the Host Adapter 50. The Sound Manager 400 will initially perform a resampling process 1020 on each input audio data stream to ensure all streams are at the same digital sample rate. Should any input audio data stream be produced at a different sample rate the sample rate will be adjusted. The audio resampler may be bypassed when the raw audio data has already been adjusted to a consistent sample rate. After each audio stream is at a particular sample rate, then an automatic noise cancellation process 1030 is run on each audio stream to remove undesired sounds. Such undesired sounds may be anything from background traffic or other ambient noise, to more foreground noise like keyboard clicking. The noise cancellation process operation is available from commercially available software packages such as Krisp.ai and open source software package sources. A representative noise cancellation processing component available from an open source software packages may be the RNNoise processing project. An automatic equalization process 1035 may be run on each audio stream to adjust the volume of different frequency bands within each audio stream to allow for an improved sound quality of each audio stream. An automatic gain control process 1040 may also be run on each audio stream to ensure that loud sources are brought down to a more reasonable level, and quieter sources have gain added to make them easier to hear. Automatic gain control process 1040 also creates a baseline audio level by which subsequent 3D spatialization processing steps can more accurately allow the participants to perceive the positional distances of other participants. In illustrative embodiments, the Sound Manager 400 comprises one or more first processing units.

For example, as depicted in FIG. 2A, the unique positions relative to the 3D map established in Environment Configuration File 320 via Environment Manager 300 and relative positional distances of each participant, including speaking and listening participants, may be ascertained. In illustrative embodiments, a virtual conference room is generated in software or updated and displayed on a host computer. This map may be called up on a potential participant's computer display screen. Each participant then accesses this map 320 from a remote computer connected to the software on the host computer via the Internet. Therefore, the direction on the map of each participant relative to the other remaining participants may be determined. (Step 1065). One or more sound directional modules including one or more algorithms for localizing sound in real-time may be utilized. Exemplative algorithms may include a Head-Related Transfer Function (HRTF) or the like. The algorithms can establish if the participants are to remain stationary, have the ability to move to specific locations, and/or have the ability to move freely around the defined map.

Once a participant's audio stream has been resampled and had noise cancellation, automatic equalization, automatic gain added, and direction determined, it is ready to be mixed for 3D spatialization. The audio stream of each participant may be processed in this manner to allow for 3D spatialization and processed input 1050, 1150, 1250 to be generated for each participant.

For each participant, the streams of all other participants is fed into the 3D Mixer 1070. This is performed as the participant does not need to hear their own audio in the on-line communications session, so it is removed from processing. So, participant 1 will have the participant 2 processed input 1150 and participant 3 processed input 1250 fed into the 3D Mixer 1070 but will not have the processed input of participant 1 1050 fed into the 3D Mixer 1070. And similarly, the inputs will be processed for the other two participants.

For each participant, the X, Y, and Z coordinates for their perceived sound location (e.g., location origin of the sound) and that of other participants is sent to the 3D mixer of their audio stream to be attenuated. This ensures all other participants appear to be in their own distinct locations in the audio landscape of the listening participant. The processed inputs 1050, 1150, 1250 then may be processed via a 3D mixer 1070 which takes in the 3D coordinates for each the participant 1075 and will mix the audio streams of all other participants so the outputs will appear audibly in the correct locations within the audio landscape in relation to the listener. The function of the 3D mixer (aka mixing engine) is further illustrated in FIG. 2D. In FIG. 2D, audio from a multiplicity of client applications 85 is processed in the mixing engine 420 to adjust the sampling rate to a consistent frequency across all client audio input streams. The mixing machine may or may not include the position location module 1065. In illustrative embodiments, the 3D mixer 1070 is associated with one or more attenuating processes 1075 configured to attenuate one or more given audio streams of a speaking participant to an attenuated audio stream such that the attenuated audio stream is representative of a distance between a speaking participant and the one or more listening participants. In other illustrative embodiment, a converter module 1078 is disclosed in communication with or a component of the 3D mixer module. The converter module 1078 is configured to convert one or more given attenuated audio streams to a converted sound corresponding to the direction of the speaking participant relative to the one or more listening participants. For example, in a virtual conference room, the converted sound received from a first position would be changed differently for sending to other positions in the environment according to the particular direction between each of the positions. A listening participant may perceive the converted sound from speakers to its right or left based on the speaker's location within the virtual room as converted by the converter module, The algorithms also can deliver different audio characteristics of the room/map (i.e. different levels of room acoustic reflectivity) in such a way as to provide the participant with a feeling as if they are in a very large space such as an auditorium or in a very small room. Moreover, in association with the converter module 1078, the sound is transformed to the sound that would be perceived by human ears in this actual situation, called binaural sound. Moreover, in association with the converter module 1078, the sound is transformed to the sound that would be perceived by human ears in this actual situation, called binaural sound. An example of this binaural sound output can be found on headphone embedded solutions from Sennheiser in their AMBEO product line. In the representative example illustrated in FIG. 2D, each audio stream is adjusted to a sampling rate of 48 kHz and then returned to the appropriate client application 85.

Referring again to FIGS. 2A-2C and FIG. 3, to enable the proper rendering of 3D spatial audio including without limitation non-headphone speaker pairs, cross-talk cancellation 1080 process is performed. This ensures that only the proper audio reaches each the left and right ear of the participant. For participants listening to the audio via headphones, this step may be bypassed. Crosstalk cancellation 1080 process uses crosstalk cancellation available from commercial software packages, such as the AudioCauldron Speaker Engine from Bit Cauldron Corporation.

As a final step, a limiting process 1090 is performed to ensure the output audio stream has limited distortions in the output. An additional master gain control process 1093 may also be performed to allow for individual source volume adjustment to ensure that the participants accurately perceive the positional distances of each of other participants.

It is noted that in FIG. 3, not all of the processing steps including for example, 1065, 1075, 1078 depicted in FIGS. 2A-2C are not shown for clarity purposes.

The processed stream is then sent back through to the UC host communication system to transmission to each participant 1095, 1195, 1295. Each participant gets a unique audio stream 1095, 1195, 1295 relative to their location in the virtual Environment. The attenuating, 3D mixing, crosstalk cancellation, and limiting process do not have to be all performed to enable the teachings of the current invention. In illustrative embodiments, the combination, (in whole or in part) of these individual transformations and enhancements and the order and manner in which they are tuned (e.g., independently) to address the unique outputs of each processing are at least some of the salient features of the system.

Each participant has their own audio transformed and/or clarified; and then the processed audio and the related data gets sent to at least one and up to all the other participants, but the sound from each individual participant is not transmitted back to themselves (so the person that is the source of the sound does not hear that particular sound from the system). This is another salient feature of the system.

The 3D coordinates 1075 for a sound source are provided by Environment Manager 300 if Sound Manager 400 is used within the Core stack.

For the input side, each of the three effects, resampling, auto noise cancellation, and auto equalization, can be separately turned on or off, e.g., activated and deactivated. The auto gain function intentionally alters a participant's current loudness to match, correspond and/or correlate to the same target loudness as all other participants which could be louder or quieter.

On the output side, similarly to the input side, each of the three effects, noise cancellation, gain, and 3D mixing, can be turned off independently within the output. Thus, an engineer or software developer that does not need 3D functioning but merely wants improved sound quality would still benefit from the unique architecture of the present invention.

In a single on-line communications session, all incoming sounds may be mixed into a single stream to be listened to by each individual participant. The Sound Manager 400 can keep the sound uttered by each participant out of this single stream tailored to that participant. Whisper mode and sidebar mode, each to be described later in this specification, may affect how many streams get mixed together and how many separate outputs there would be and limit the sounds heard by an individual participant.

Referring again to FIG. 2A, a representative example of the processing steps for the application in which the Core resides with the host is provided. As with the example illustrated in FIG. 3, the raw input into the Sound Manager is typically processed through the audio resampler 1020, auto noise cancellation 1030, automatic equalization 1035, automatic gain control 1040, determining relative positions of the participants 1065, mixing via the 3D mixer 1070, crosstalk cancellation 1080, limiting process via the limiter 1090, and individual source volume adjustment via the master gain control 1093 are performed. In this case, the Sound Manager 400 will receive a raw audio feed from the host adapter 50 and will transmit a processed audio feed back to the host adapter 50. Information from the Environment Manager 300 and the Event Manager 200 provide data to generate the desired 3D sound to be transmitted back to the at least one client via the host.

Referring again to FIG. 2B, a representative example of the processing steps for the application in which the Core resides with the at least one client is provided. As with the example illustrated in FIG. 3, the raw input into the Sound Manager is typically processed through the audio resampler 1020, auto noise cancellation 1030, automatic equalization 1035, automatic gain control 1040, 3D mixing via the 3D mixer 1070, crosstalk cancellation 1080, limiting process via the limiter 1090, and individual source volume adjustment via the master gain control 1093 are performed. In this application, the Sound Manager 400 will receive a raw audio feed from each client application 85 and will transmit a processed audio feed back to each client application 85. Information regarding the virtual surroundings are provided from the Environment Manager 300 and from the Event Manager 200 via at least one client applications 85 to provide data to generate the desired 3D sound to be transmitted back to the at least one client via the at least one client adapter.

As illustrated in FIG. 2C, the Core and specifically the Sound Manager 400 may reside on both the host and at least one client application.

### DETAILED EXAMPLES OF PROCESS MODULES SUITABLE FOR USE IN SOUND MANAGER

### Example—Automatic Noise Cancellation (Noise Cancellation Process 1030)

An Automatic Noise Cancellation (ANC) module suitable for use as the Noise Cancellation Process 1030 receives a block of digital audio, runs it through a neural network and outputs the same audio block with speech maintained and noise reduced. In illustrative embodiments, this exemplary Automatic Noise Cancellation module of the Application chains two open-source neural network models together in a new way to modify different qualities of noisy speech audio.

The first neural network is Dual-Signal Transformation LS™ Network (DTLN), such as is available from https://github.com/breizhn/DTLN. This network was originally trained for 16 kHz digital audio, with a block length of 512 samples and block shift of 128 samples. In illustrative embodiments, the process is retrained to process 48 kHz digital audio with a block length of 480 samples and block shift of 240 samples to better match our audio pipeline. The training process used a dataset that mixed high quality speech (https://zenodo.org/record/4660670 and https://datashare.ed.ac.uk/handle/10283/2791) with more naturalistic speech (https://commonvoice.mozilla.org/en/datasets). However, this network may be overactive at noise cancellation, leaving undesirable artifacts in the processed audio.

The second neural network of this exemplary Automatic Noise Cancellation module is RNNoise available at (https://github.com/sleepybishop/rnnoise/tree/with_fixes). This network works to smooth out many of the artifacts that exist in the output of DTLN.

Additionally, RNNoise includes a Voice Activity Detection (VAD) network that outputs a prediction of voice presence in the audio block as well as a pitch detection network.

In illustrative embodiments, for more efficient computing, the voice prediction may be fed into our AGC module (block 1040) and the pitch detection into the AEQ module (block 1035), and therefore save the compute cost of having to perform these processes twice.

### Example—Automatic Equalization (Automatic Equalization (EQ) Control Process 1035)

When people speak over real time communication systems, their devices, setup, or usage may result in poor qualities such as resonances or notches which cause a non-optimal spectral character. This characteristic would then manifest as reduced capability of comprehending words. The traditional solution to this is to use a manual audio equalization to repair these defects, but regular users are not knowledgeable or trained in the art of this specific task.

A new Automatic Equalization module suitable to provide the Automatic Equalization (EQ) Control Process 1035 is now described in detail. In illustrative embodiments, via this Automatic Equalization module, audio equalization may be automatically performed, thereby solving the problem of resonances or notches which cause a non-optimal spectral character for all users.

The steps (0-3) are as follows:

0. Before real time processing
a. A target curve is created which maps one or more desired spectral characters for the input speech signal. Normally, the pitch versus the pitch of the input speech is considered. However, in illustrative embodiments, the system incorporates features to generalize this target to all speech inputs in step 1ci

1. Analysis
a. Perform FFT on a block of the input signal.
b. If the voice activity detection (from the noise cancellation module) is below the threshold, skip remainder of analysis. This prevents the system from adjusting the filter based on sounds which are not the user's voice.
c. Use the current block's pitch to update our fundamental pitch estimate
   i. Adjust the target curve to match the fundamental pitch. Frequencies below 1 kHz are sensitive to the pitch and harmonics and must be adjusted. Frequencies above 1 kHz are not sensitive and are not adjusted.
d. Use the current frame's RMS to update our input loudness estimate
e. Perform time averaging on the input's frequency spectra. This provides smoothing which reduces the impact of transient peaks and notches in the frequency spectra over time.
f. Find the difference between the target curve and the time averaged input curve. The differences may be generated into a number of bands in order to better generalize the difference against very specific pitch peaks and notches.
g. Using the differential gain in each band, perform cubic interpolation to produce an extremely smooth transfer function. This sin-like interpolation is much more natural for audio filtering and will cause substantially less artifacts than direct transfer functions.
h. Save this transfer function using standard DSP practices for use in step 2.

2. Filtering
a. Perform convolution of the input signal and the filter obtained in step 1h to generate the enhanced speech.

3. Post-processing
a. If the voice activity for the input frame is above the threshold, use the output generated in step 2a to update the output loudness estimate.
b. Use the difference of the loudness' obtained in steps 1d and 3a to normalize the output of step 2a to match the loudness of the input frame. This step prevents the loudness from changing when the effect is bypassed versus engaged.

### Example—Automatic Gain Control (Automatic Gain Control Process 1040)

Automatic Gain Control is typically a gradual correction (over the course of seconds) meant to generally adjust the microphone gain to make up for quiet or loud talkers. By contrast, in illustrative embodiments, the new AGC of the detailed example, is sufficiently and/or rapidly (e.g., in real-time) to maintain a constant level of speech volume during short segments of speech where volume might change. In virtual communications, an important use case of this new Automatic Gain Control, is where someone turns away from or towards their microphone in the middle of a sentence, which would typically cause a sharp change in their perceived volume. As described in detail hereinbelow, the Automatic Gain Control is responsive (e.g., close or in real-time) to maintain a constant level of speech volume during short segments of speech. The Automatic Gain Control detects and accounts for this, while maintaining the original character of the voice, i.e., not producing any “over-compressed” artifacts.

The following steps may be performed on each block of sound:

1. Apply an equal loudness filter. This filters the audio according to the natural frequency curve of human hearing, ensuring the RMS calculated in step 2 is representative of how humans actually perceive the loudness.

2. Calculate the RMS of this filtered signal (the power)

3. Utilize three (3) power measurements: The power calculated in step 2 (power), the power from the previous block (power_prev) and a recursively averaged measurement of power over time (power_avg).
a. The recursive function used: power_avg=(alpha*power_avg)+(1−alpha)*power.

4. The alpha constant of the algorithm used to find power_avg is changed depending on power and power_prev. For example, if there is a sudden increase from power_prev to power, then we decrease alpha, making the recursive algorithm more sensitive to the newest data.
a. Additionally, power_avg is only updated with the recursive averaging if our Voice Activity Detector (from the noise cancellation module) is above a certain threshold of confidence. This ensures that we do not change alpha based on the power of background noise, only speech.

5. By comparing power_avg with our ideal power, we find a gain factor (K) with which to amplify the signal to reach the target power.

6. Some modifications to K are then made. First, if our Voice Activity Detector determines that there has not been speech in a while, we slowly begin to decrease K. This helps ensure that a large K value does not “persist” and create very loud audio when someone begins talking again. (Ends of sentences are often quieter than beginnings/interjections)

7. Second, K is limited to be within a certain range to ensure it does not somehow create a massive gain spike.

8. Finally, K is applied to the signal to change the volume.

### Environment Manager

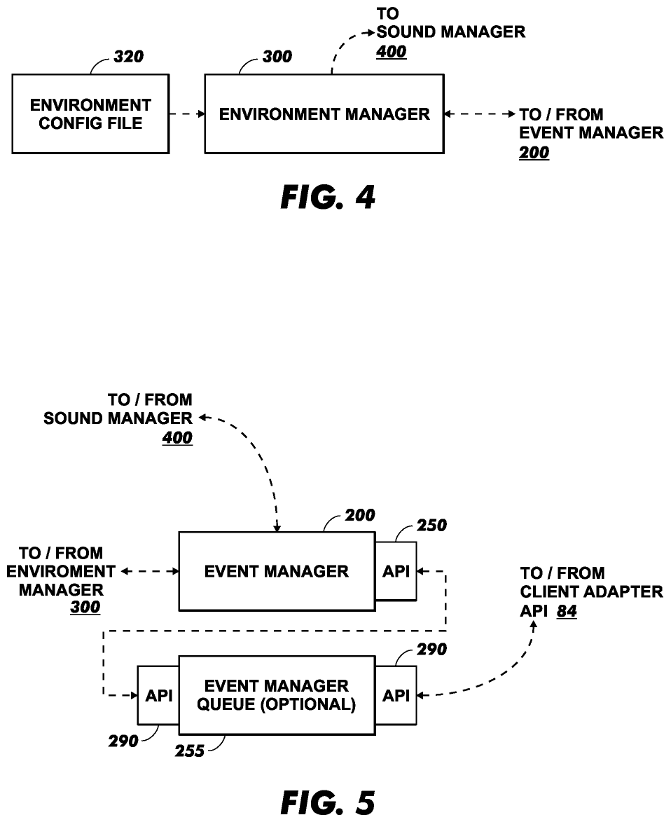

FIG. 4 provides an overview of the function of the Environment Manager 300. Environment Manager 300 provides a simplified version for putting the sounds to a particular location and then transferring the sound to the Sound Manager 400. Environment Manager 300 provides a mapping from the virtual seat within the virtual room environment and assigns it a particular location for that seat. As a representative example of a three participant meeting or event, an on-line communications session administrator will set up a location for seats 1, 2, and 3 and then each user will simply chooses which seat he or she wants to sit in. Environment Manager 300 accommodates the mapping of seats and participant seat selection. In illustrative embodiments, the Environment Manager 300 initially generates a map or 3D mapping 320 for, in one example, a virtual conference room map, for display for the one or more participants. Each potential user, i.e. a participant, can access the map 320 from a remote computer connected to the software on the host computer via the Internet. As note hereinabove, the Environment Manager may comprise a second processing unit.

Environment Manager 300 is the main interface for the Sound Manager 400 in the Core 100 stack. In addition to managing environment parameters like the location of a seat in a conference session, acoustic properties, and environment limits, Environment Manager 300 also notes a mapping between a defined participant seat in the virtual environment and the seat's specific 3D (X, Y, Z) coordinates, for example, and generate a mapping or map 320 as noted above.

Messages that change the environment or participant values are processed in real-time and send to the Sound Manager 400. Sound Manager 400 then accordingly adjusts the audio mixing.

When Environment Manager 300 is initiated, it looks for and reads in a configuration file 320. The configuration file 320 defines all the available environments and the unique attributes for each one. Each environment defined in the configuration file has the environment parameters such as virtual room dimensions, objects such as columns, stairs, or the like that may be present in the room, seats with X, Y, Z coordinates, and other attributes specified. This allows Environment Manager 300 to know the precise location for each defined participant location in the virtual environment set up for the particular event being attended. In some embodiments, the Environment Manager generates a Map 302.

The Sound Manager 400 receives all meeting change data including data associated with movement of the participants and changes in voice data through the Environment Manager 300.

The Event Manager 200 can send changes requested from an authorized client application or the host communication system to the Sound Manager 400 via the Environment Manager 300. This allows command messages to be simplified and manage only variables that effect the acoustic profile experienced by a user in a particular seat for things like user movements, sound settings changes, and the like.

### Event Manager

Referring to FIG. 5, an exemplary Event Manager 200 of the present invention is illustrated. The Event Manager 200 acts as a message broker, relaying received messages to the proper internal or external processing components. Event Manager 200 enables messages to be sent from a client application 85 via a client adapter 80 to notify the Core system 100 and other attached participants in a meeting of events like people joining a session, leaving a session, or moving to a new location. These notifications are provided through messages sent over a secure WebSocket connection 290 between the client and the Event Manager API 250. The Event Manager API 250 is an extension of the main Event Manager 200 code which provides a secure websocket connection 290 for end-user client applications to connect to via client adapters 80. The websocket connection 290 allows for bi-directional command messages between the client application 85 and the Event Manager 200. The Event Manager API 250 allows all clients to receive updates regarding the state of the meeting and participants, as well as send commands to the Core to effect changes as needed. Changes sent from an authorized client via the client adapter API 84 to the Event Manager 200 may be re-broadcast to all participants in a meeting, ensuring all client applications stay coordinated. When messages from clients get sent to the Event Manager 200, the Event Manager 200 will determine where to relay the properties of the events, be it to notify the Sound Manager 400 of a participant location change, an audio profile change for a participant, or other setting affecting the audio for a participant. When Event Manager 200 receives a message to add, delete, or otherwise change an on-line communications session or participant, the Event Manager 200 relays the command to the Environment Manager 300 for processing the task. Upon task completion, or upon error should the commanded task be unperformable, a return message is sent to the Event Manager 200. An optional Event Manager queue 255 may be provided to allow for continual data and audio processing in the event of network disruptions which allows for seamless or nearly seamless processing of the audio and data streams even in less than ideal conditions.

As previously described, the client adapter 80 is software provided to a vendor which allows their client application to communicate to the Event Manager API 250. The client adapter 80 also listens for changes received from the Event Manager 200 so the client application can respond to changes to the meeting. There is a one-to-many relationship between the Event Manager API 250 and all the connected clients. That is, there may be many instances of the end-user application connected simultaneously to the Event Manager API 250 for a given meeting.

The Event Manager 200 also sends messages back to an end user via the client application 85 so that the client application user interface can be updated, e.g., a participant icon, may be moved to a new virtual location within the meeting room, or the user may receive an indication that a setting has been turned off or turned on. While this can be very complex behind the scenes, the end user is provided a simple clear experience on the end user interface of the client application.

The Core library provides an interface to the host adapter. This library will send pertinent events from the host communication system to Event Manager. This is performed in the compiled code, and not through a web-accessible API. Through a reverse mechanism, Event Manager can send messages back to the host communication system via calls to the Core interface.

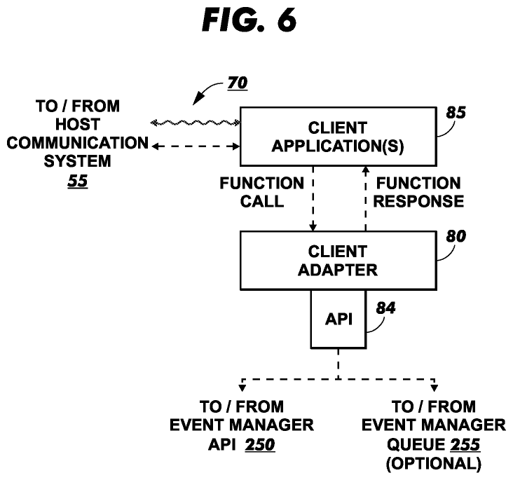

Referring to FIG. 6, in cases where it is preferable to send client application data, such as participant coordinates or settings updates, directly to Sound Manager versus routing that data through the host communication system 55 which may add latency or unpredictable performance, the client adapter 80 is used to create a secure data link and pass data between the client application 85 via the client adapter API 84 and Core via the Event Manager API 250. To maintain the quality of the audio data and avoid and/or reduce latency effects an Event Manager queue 255 may be used while communicating between the client adapter API 84 and the Event Manager API 250. As noted hereinabove, the Event Manager 250 may comprise a third processing unit.

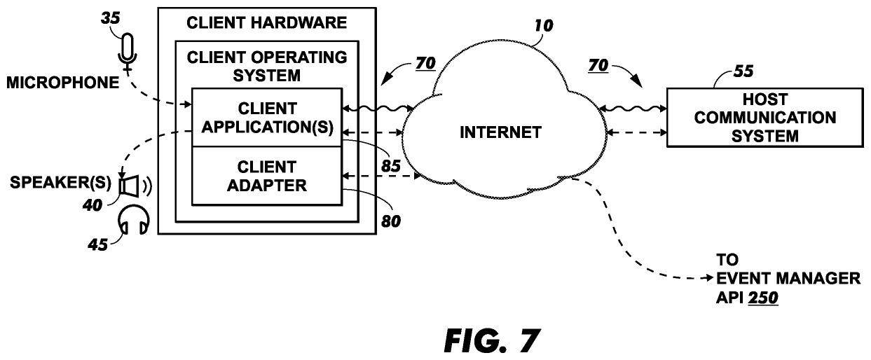

Referring to FIG. 7, in illustrative embodiments, the system may be implemented over a communication network such as the internet 10. Both the client system 70 and the host communication system 55 can communicate with each other and the Core via the Event Manager 250. Data and raw and processed audio are transmitted between the individual stakeholders and processing components via the internet in one preferred embodiment of the present invention.

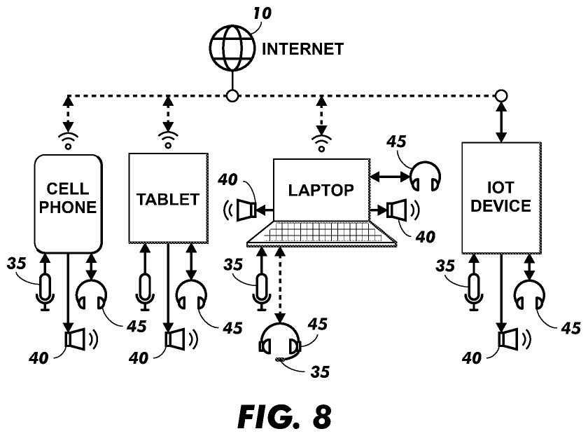

FIG. 8 provides a representation of a few of the myriad of devices that may be used by participants in an on-line communication session. Each of the participants may be connected to each other participant through the internet 10. Devices such as cell phones, tablets, laptops, or other internet of things (IoT) devices such as cameras, microphones, RFID sensors and the like may each individually be equipped with a microphone 35, speaker 40, headset 45, or other communication means to interact with other participants in the communication session.

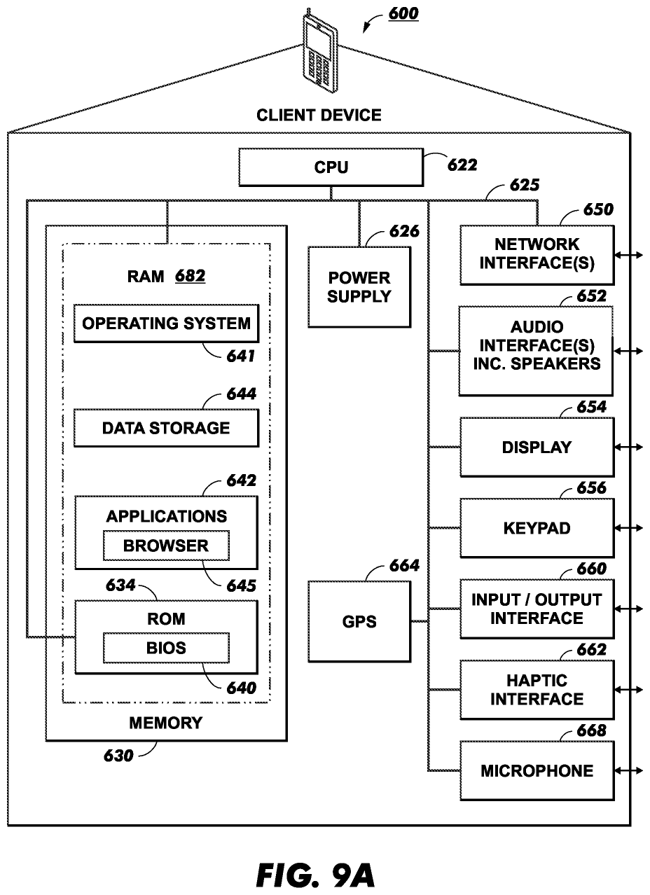

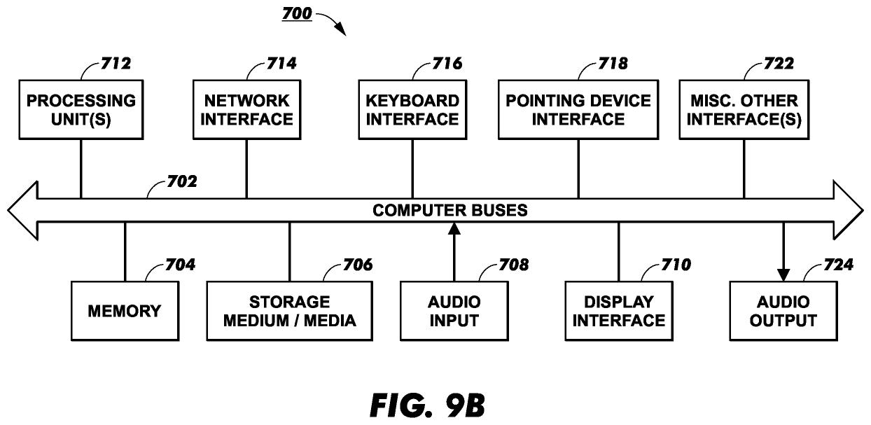

Referring to FIG. 9A from this description it will be appreciated that certain aspects are embodied in the user devices, certain aspects are embodied in the server systems, and certain aspects are embodied in a client/server system as a whole. Embodiments disclosed can be implemented using hardware, programs of instruction, or combinations of hardware and programs of instructions.

In general, routines executed to implement the embodiments may be implemented as part of an operating system or a specific application, component, program, object, module or sequence of instructions referred to as “computer programs.” The computer programs typically comprise one or more instructions set at various times in various memories and storage devices in a computer, and that, when read and executed by one or more processors in a computer, cause the computer to perform operations necessary to execute elements involving the various aspects.

While some embodiments have been described in the context of fully functioning computers and computer systems, those skilled in the art will appreciate that various embodiments are capable of being distributed as a program product in a variety of formats and are capable of being applied regardless of the particular type of machine or computer readable media used to actually effect the distribution.

Examples of computer readable media include but are not limited to recordable and non-recordable non-transitory computer readable type media such as volatile and non-volatile memory devices, read only memory (ROM), or random access memory. In this description, various functions and operations are described as being performed by or caused by software code to simplify description. However, those skilled in the art will recognize what is meant by such expressions is that the functions result from execution of the code by a processor, such as a microprocessor.

FIG. 9A shows one example of a schematic diagram illustrating a client device 600 upon which an exemplary embodiment of the present disclosure may be implemented. Client device 600 may include a computing device capable of sending or receiving signals. such as via a wired or wireless network. A client device 600 may for example include a desktop computer or a portable device. such as a cellular telephone. a smartphone, a display pager, a radio frequency (RF) device. an infrared (IR) device, a personal digital assistant (PDA), augmented reality glasses. a handheld computer, a tablet computer, a laptop computer, a digital camera, a set top box, a wearable computer, an integrated device combining various features, such as features of the foregoing devices, or the like.

The client device 600 may vary in terms of capabilities or features. Claimed subject matter is intended to cover a wide range of potential variations. For example, a cell phone may include a numeric keypad or a display of limited functionality, such as a monochrome liquid crystal display (LCD) for displaying text, pictures, etc. In contrast, however, as another example, a web-enabled client device may include one or more physical or virtual keyboards, mass storage, one or more accelerometers, one or more gyroscopes, global positioning system (GPS), or other location-identifying type capability of a display with a high degree of functionality, such as a touch sensitive color 2D or 3D display, for example. Other examples included augmented reality glasses and tablets.

A client device 600 may include or may execute a variety of operating systems, including a personal computer operating system, such as a Windows, MacOS, or Linux, or a mobile operating system, such as iOS, Android or the like. A client device may include or may execute a variety of possible applications, such as a client software application enabling communication with other devices, such as communicating one or more messages, such as via email, short message service (SMS), or multimedia message service (MMS), including via a network, such as a social network, including, for example, Facebook®, LinkedIn®, Twitter®, Flickr®, or Google+®, to provide only a few possible examples. A client device may also include or execute an application to communicate content, such as, for example, textual content, multimedia content, or the like. A client device may also include or execute an application to perform a variety of possible tasks, such as browsing, searching, playing various forms of content, including locally stored or streamed video, or games (such as fantasy sports leagues). The foregoing is provided to illustrate that claimed subject matter is intended to include a wide range of possible features or capabilities.

As shown in the example of FIG. 8A, client device 600 may include one or more processing units (also referred to herein as CPUs) 622, which interface with at least one computer bus 625. A memory 630 can be persistent storage and interfaces with the computer bus 625. The memory 630 includes RAM 632 and ROM 634. ROM 634 includes a BIOS 640. Memory 630 interfaces with computer bus 625 so as to provide information stored in memory 630 to CPU 622 during execution of software programs such as an operating system 641, application programs 642 such as device drivers (not shown), browser module 645, that comprise program code, and/or computer-executable process steps, incorporating functionality described herein, e.g., one or more of process flows described herein. CPU 622 first loads computer-executable process steps from storage, e.g., memory 632, data storage medium/media 644, removable media drive, and/or other storage device. CPU 622 can then execute the stored process steps in order to execute the loaded computer-executable process steps. Stored data, e.g., data stored by a storage device, can be accessed by CPU 622 during the execution of computer-executable process steps.

Persistent storage medium/media 644 is a computer readable storage medium(s) that can be used to store software and data, e.g., an operating system and one or more application programs. Persistent storage medium/media 644 can also be used to store device drivers, such as one or more of a digital camera driver, monitor driver, printer driver, scanner driver, or other device drivers, web pages, content files, playlists and other files. Persistent storage medium/media 606 can further include program modules and data files used to implement one or more embodiments of the present disclosure.

For the purposes of this disclosure a computer readable medium stores computer data, which data can include computer program code that is executable by a computer, in machine readable form. By way of example. and not limitation, a computer readable medium may comprise computer readable storage media, for tangible or fixed storage of data, or communication media for transient interpretation of code containing signals. Computer readable storage media, as used herein, refers to physical or tangible storage (as opposed to signals) and includes without limitation volatile and nonvolatile, removable and non-removable media implemented in any method or technology for the tangible storage of information such as computer-readable instructions, data structures, program modules or other data. Computer readable storage media includes, but is not limited to, RAM, ROM, EPROM, EEPROM, flash memory, or other solid state memory technology, CD-ROM, DVD, or other optical storage, magnetic cassettes, magnetic tape, magnetic disk storage or other magnetic storage devices, or any other physical or material medium which can be used to tangibly store the desired information or data or instructions and which can be accessed by a computer or processor.

Client device 600 can also include one or more of a power supply 626, network interface 650, audio interface 652, a display 654 (e.g., a monitor or screen), keypad 656, I/O interface 660, a haptic interface 662, a GPS 664, and/or a microphone 668.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium. Modules may be integral to one or more servers, or be loaded and executed by one or more servers. One or more modules may be grouped into an engine or an application.

FIG. 9B is a block diagram illustrating an internal architecture 700 of an example of a computer, such as server computer and/or client device, in accordance with one or more embodiments of the present disclosure. A computer as referred to herein refers to any device with a processor capable of executing logic or coded instructions, and could be a server, personal computer, set top box, tablet, smart phone, pad computer or media device, or augmented reality glasses, to name a few such devices. As shown in the example of FIG. 9B, internal architecture 700 includes one or more processing units (also referred to herein as CPUs) 712, which interface with at least one computer bus 702. Also interfacing with computer bus 702 are persistent storage (non-transitory) medium/media 706, network interface 714, memory 704, e.g., random access memory (RAM), run-time transient memory, read only memory (ROM), etc., display interface 710 as interface for a monitor or other display device, keyboard interface 716 as interface for a keyboard, pointing device interface 718 as an interface for a mouse or other pointing device, an audio input 709 as a microphone or other listening device, an audio output 724 as a speaker, ear bud, or other such device, and miscellaneous other interfaces 722 such as parallel and serial port interfaces, a universal serial bus (USB) interface, Apple's ThunderBolt™ and Firewire™ port interfaces, and the like.

Memory 704 interfaces with computer bus 702 so as to provide information stored in memory 704 to CPU 712 during execution of software programs such as an operating system, application programs, device drivers, and software modules that comprise program code, and/or computer-executable process steps, incorporating functionality described herein. e.g., one or more of process flows described herein. CPU 712 first loads computer-executable process steps from storage, e.g., memory 704, storage medium/media 706, and/or other storage device. CPU 712 can then execute the stored process steps in order to execute the loaded computer-executable process steps. Stored data, e.g., data stored by a storage device, can be accessed by CPU 712 during the execution of computer-executable process steps.

As described above, persistent storage medium/media 706 is a computer readable storage medium(s) that can be used to store software and data. e.g., all operating system and one or more application programs. Persistent storage medium/media 706 can also be used to store device drivers, such as one or more of a digital camera driver, monitor driver, printer driver, scanner driver, or other device drivers, web pages, content files, playlists, and other files. Persistent storage medium/media 706 can further include program modules and data files used to implement one or more embodiments of the present disclosure.

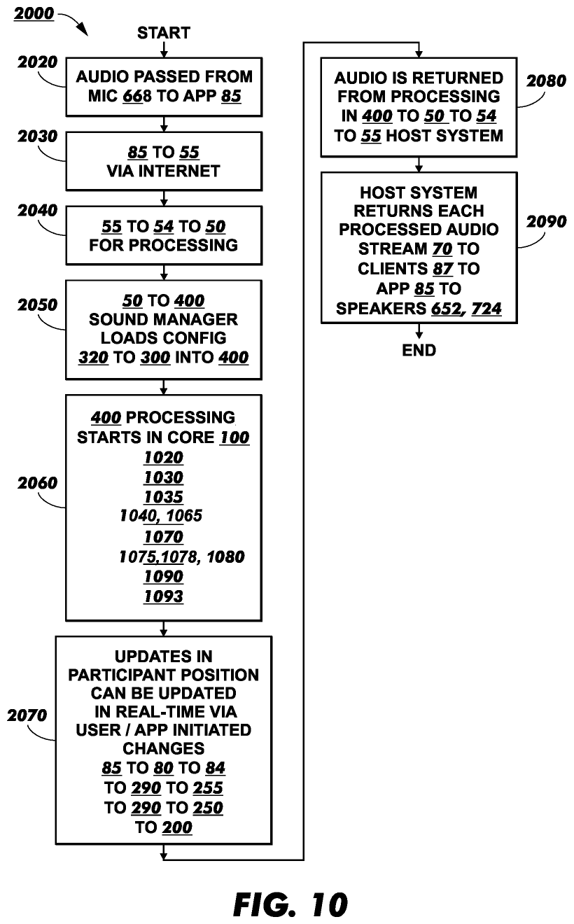

Referring to FIG. 10 an exemplary process 2000 for using the system is illustrated. In step 2020 audio is heard by a microphone 668 and is captured to a client ecosystem and more specifically a client application 85 as described, for example, in FIGS. 1B and 1C. In step 2030 this audio and data is transmitted to a host communication system 55 via a transmission media such as the internet. The audio and data may also be transmitted via other communications methods such as a WiFi connection on a network. In step 2040 the raw data and audio are transferred to a host API 54 to transmit to a host adapter 50 which will then communicate with a Sound Manager 400 in step 2050. The Sound Manager 400 will take the raw data and audio and begin to process the raw audio and raw data based upon the virtual room's environmental properties which are stored in an environment configuration file 320 and are brought into the Core 100 via an Environment Manager 300. In process 2060, the Sound Manager processes the audio in the Core 100 via one of the processes illustrated in FIGS. 2A, 2B, and 2C described above. In illustrative embodiments, the raw audio and the raw data include voice and positional data.

Upon processing the data in the Core 100, any changes to the participants' relative positions may be updated dynamically, e.g., in real-time including such items as a participant leaving the meeting or another participant entering the meeting. There are many other changes that can be made to a participant's location such as moving to a different location within the configuration of the virtual meeting room or entering a sidebar room, the details of which will be discussed in the next section of this specification.

Upon performing the transformations of audio in step 2060 and accounting for participant changes in step 2070, the processed audio is returned to the host communication system in step 2080. The processed audio stream is then returned to the individual clients from the host communication system where it may be heard by the individual participants in the conference via headphones, speakers, or other sound generation equipment (Steps 2080 and 2090). 3

### Additional Components

Whisper Mode and Sidebar Mode

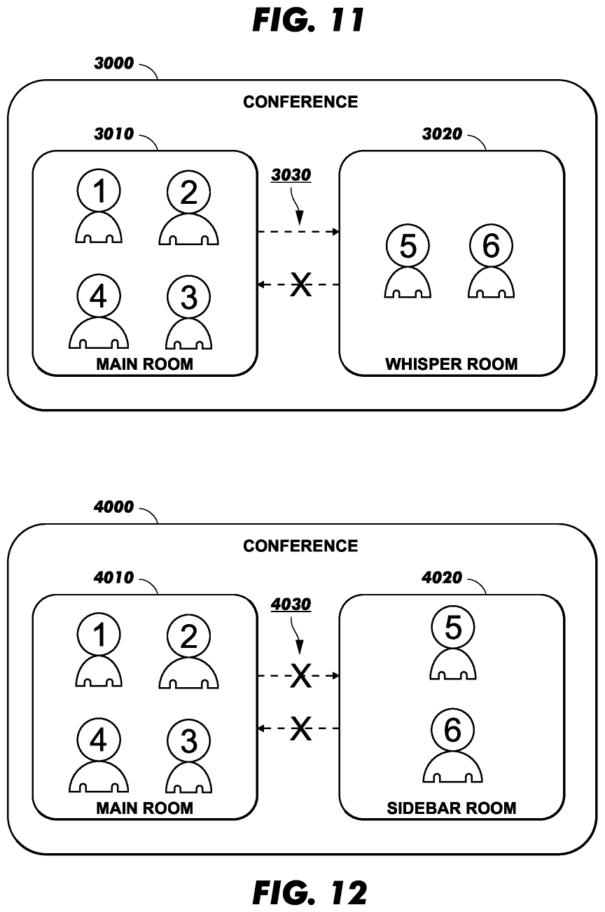

Referring to FIG. 11, a system to allow for defined participants to speak to other defined participants that may be located near them in the virtual environment and/or as a pre-defined sub-group within the conference while still hearing what the other participants in the room is presented. A conference room 3000 is presented which has both a main room 3010 and at least one whisper room 3020. For simplicity only a single whisper room 3020 is presented in the example. All participants in the conference room 3000 can hear all participants located in the main room 3010. But defined participants (as noted above) are able to move to the whisper room 3020 and those participants within the whisper room can hear everything said by the other participants inside both the whisper room and the main room 3010 but those in the main room 3010 cannot hear what is said in the whisper room 3020. Communication 3030 between the two rooms flows in only one direction—from the main room 3010 to the whisper room 3020. In whisper mode, a participant can talk and still hear everything else going on in the main room. Participants in the main room can hear and/or interact with other participants but cannot hear audio from participants in the whisper room 3020. Those participants in the whisper room can hear each other and can also hear audio from participants in the main room. Typically, the audio the whisper room participants hear from those located in the main room is heard at a reduced volume to improve the clarity of the conversations held in the whisper room. A conference may have multiple whisper rooms functioning at any given time. Audio in the whisper room is not heard by all meeting room participants. A whisper room may have two or more participants.

A participant in a whisper room will hear all sources from the main room and all sources in the whisper room. A participant in the whisper room will act as a source only for listeners in the same whisper room.

Referring to FIG. 12, a system to allow for participants to leave the main conference room 4000 virtually and move to a new separate virtual environment is provided. The participants in a sidebar room will not hear participants in the main room and participants in the main room will not hear those located in the sidebar room. A conference room 4000 is presented which has both a main room 4010 and at least one whisper room 4020. For simplicity only a single sidebar room 4020 is presented in the example. Only participants in the main room 4010 can hear all participants located in the main room 4010. Participants that move to the sidebar room 4020 can only hear things said by the other participants inside the sidebar room 4020 and those in the main room 4010 cannot hear what is said in the sidebar room 4020. Communication 4030 between the two rooms does not occur. Sidebar mode is like going to a mini-breakout environment—a participant cannot hear any of the other participants that are not in the sidebar. Participants in the main room can hear and/or interact with other participants but cannot hear audio from participants in the sidebar room 4020. Those participants in the sidebar room can hear each other but cannot also hear audio from participants in the main room. A conference may have multiple sidebar rooms functioning at any given time. Audio in the whisper room is not heard by all meeting room participants. A sidebar room may have two or more participants.

A participant in a sidebar room will hear only sources in the same sidebar room. A participant in a sidebar room will act as a source only for participants in the same sidebar room as them.

A participant in both a whisper room and a sidebar room will hear all sources from the sidebar room and all sources in the whisper room. A participant in both a whisper room and a sidebar room will act as a source only for listeners in the same sidebar room.

A participant who is not in any whisper or sidebar room will be considered to be in the main room. A participant in the main room will only hear sources that are also not in any whisper or sidebar room. A participant in the main room will only act as a source for listeners in the main room or listeners in any whisper room.

Although several embodiments of the present invention, methods to use said, and its advantages have been described in detail, it should be understood that various changes, substitutions, and alterations can be made herein without departing from the spirit and scope of the invention as defined by the appended claims. The various embodiments used to describe the principles of the present invention are by way of illustration only and should not be construed in any way to limit the scope of the invention. Those skilled in the art will understand that the principles of the present invention may be implemented in any suitably arranged device.

Moreover, exemplary embodiments have been described herein with reference to the accompanying figures, it is to be understood that the disclosure is not limited to those precise embodiments, and that various other changes and modifications may be made therein by one skilled in the art without departing from the scope of the appended claims.

What is claimed is:

1. A computer implemented multi-dimensional audio conferencing method for audio and related data processing of noise cancellation, participant voice clarity enhancements, and immersive 3D spatial audio output to participants in an audio or video on-line communications ecosystem comprising:
in one or more first processing components:
receiving from on-line communication participants audio streams;
resampling the audio streams to ensure the audio streams are sampled at the same sample rate;
removing noise via a noise cancellation process executed on the audio streams;
executing an equalization process to improve sound quality of the audio streams; and
leveling the audio streams to a common volume level for the participants; and
in one or more second processing components:
receiving, as input, the leveled audio streams;
assigning each participant to a 3D unique position on a computer generated map;
determining a direction on the map of each participant relative to the other remaining participants;
attenuating a given audio stream of a speaking participant to an attenuated audio stream such that the attenuated audio stream is representative of a distance between a speaking participant and the one or more listening participants;
converting the given attenuated audio stream to a converted sound corresponding to the direction of the speaking participant relative to the one or more listening participants;
for at least some of the listening participants, performing crosstalk cancelation on the converted sound; and
performing a limiting process on each converted audio stream.

2. The method according to claim 1 further comprising running an additional audio gain control process on each limited audio stream.

3. The method according to claim 1 further comprising adjusting, by the first processing component, the number of participants in the on-line communications ecosystem and/or the position, and further including:
assigning, via the second processing component and a third processing component, each conference participant to a unique position on the computer generated map based upon the data stream related to each leveled audio stream.

4. The method according to claim 1 including dynamically assigning one or more each participants respective unique position on the computer generated map.

5. An automatic equalization process for an audio or video on-line communications system comprising:
providing a processor to run said automatic equalization process with a generalized target curve which maps a spectral character of speech of a typical on-line communications participant audio;
receiving from an on-line communications participant, an audio stream into said processor;
based on a frequency domain analysis by said processor of at least one block of said audio stream, adjusting said generalized target curve to match a fundamental pitch of said on-line communications participant by said processor to generate an adapted target curve;
generating by said processor a transfer function for a filter based on said adapted target curve; and
convolving by said processor said audio stream with said filter to provide substantially in real time an enhanced speech.

6. The automatic equalization process of claim 5, wherein said step of based on said frequency domain analysis of said at least one block of said audio stream, adjusting comprises performing an FFT of said at least one block of said audio stream.

7. The automatic equalization process of claim 5, wherein following said step of receiving, a further step of detecting a voice activity of said on-line communications participant, and where a detection of said voice activity is below a predetermined threshold, performing again said step of receiving said audio stream to prevent a filter adjustment based on a sound which is not a user's voice.

8. The automatic equalization process of claim 5, wherein following said step of adjusting, a further step of calculating an RMS loudness estimate of said audio stream of said on-line communications participant.

9. The automatic equalization process of claim 5, wherein said step of generating said transfer function further comprises a time averaging of a spectra of said at least one block of said audio stream to reduce artifacts caused by transient peaks of the spectra.

10. The automatic equalization process of claim 5, wherein said step of generating said transfer function comprises a cubic interpolation.

11. The automatic equalization process of claim 6, further comprising after said step of convolving, a post processing step, wherein if a voice activity is above a threshold, updating a loudness estimate based on said FFT.

12. The automatic equalization process of claim 11, wherein following said step of adjusting, a further step of calculating an RMS loudness estimate of said audio stream of said on-line communications participant, and using a difference of said output loudness estimate and said RMS loudness estimate to prevent changes in loudness when changing engaging or bypassing an effect mode.

13. An automatic gain control process for an audio or video on-line communications system comprising:
providing a process to run said automatic gain control process with an equal loudness filter which filters audio according to a natural frequency curve of human hearing;
receiving from an on-line communications participant, an audio stream into said processor;
filtering at least one block of said audio stream by said equal loudness filter to generate a filtered audio stream block;
calculating by said processor a gain factor K based on an RMS power of said filtered audio stream block, a RMS power of a previous filtered audio stream block; and an average power measurement of two or more of said filtered audio stream blocks; and
applying by said processor said gain factor K to said audio stream to maintain substantially in real time, a desired volume for said on-line communications participant.

14. The automatic gain control process according to claim 13, wherein said step of calculating said gain factor K, comprises calculating said gain factor K up to a predetermined maximum gain factor K limit.

15. The automatic gain control process according to claim 14, wherein said step of calculating said gain factor K, comprises calculating said gain factor K based on a recursive average power calculation.

16. The automatic gain control process according to claim 15, wherein said step of calculating said gain factor K based on said recursive average power calculation comprises calculating said gain factor K based on said recursive average power calculation where said average power measurement is more sensitive to one or more most recent audio stream blocks.

17. The automatic gain control process according to claim 16, further comprising before said step of calculating said gain factor K, detecting a presence of said on-line communications participant by a voice activity detector, and wherein performing said step of calculating said gain factor K with said recursive average power calculation only if said voice activity detector provides a voice activity value above a predetermined threshold.

18. The automatic gain control process according to claim 16, wherein said step of calculating said gain factor K, comprises comparing said average power measurement of two or more of said filtered audio stream block to a desired average power and further modifying said gain factor K to reach a target power.

19. The automatic gain control process according to claim 15, further comprising before said step of calculating said gain factor K, detecting a presence of said on-line communications participant by a voice activity detector, and if said voice activity detector provides a voice activity value below a predetermined threshold indicating a period of no voice activity, said gain factor K is decreased over time.

20. A computer system comprising:
a memory storing instructions: and
a processor coupled with the memory to execute the instructions, the instructions configured to instruct the processor to provide clear immersive 3D audio to participants in an audio or video on-line communications ecosystem;
receive, by the processor, from each on-line communications participant an audio stream and a related data stream into a first processing component;
resample, by the first processing component, each received audio stream to ensure all audio streams are sampled at the same sample rate;
remove noise, by the first processing component, via a noise cancellation process on each resampled audio stream;
improve the sound quality, by the first processing component, via an automatic equalization process on each noise removed audio stream;
level, by the first processing component, via an automatic gain control process on each improved sound quality audio stream;
3D spatialize, by the first processing component, the leveled audio stream from each speaking participant to each other listening participant; said spatialization comprising assigning, via a second processing component, each conference participant to a unique position on a computer generated map based upon the data stream related to each leveled audio stream, wherein the plurality of conference participants includes speaking participants and listening participants;
determining a direction on the map of each participant from each other participant, attenuating, by the first processing component, the 3D spatialized audio stream to an attenuated audio stream such that the attenuated audio stream is representative of a distance between the one speaking participant and each of the listening participants; and
converting, by the first processing component, the attenuated voice sound to a converted sound corresponding to the direction to each of the listening participants from the speaking participant;
for each participant listening to the conference via a means other than headphones, perform, by the first processing component, crosstalk cancelation on each said converted audio stream; and
perform, by the first processing component, a limiting process on each converted audio stream.
